(19) United States
(12) Patent Application Publication
(10) Pub. No.: US 2011/0034008 A1
(43) Pub. Date: Feb. 10, 2011

(54) METHOD FOR FORMING A TEXTURED SURFACE ON A SEMICONDUCTOR SUBSTRATE USING A NANOFABRIC LAYER

(75) Inventor: Sohrab Kianian, Los Angeles, CA (US)

Correspondence Address: WILMERHALE/BOSTON, 60 STATE STREET, BOSTON, MA, 02109, US

(73) Assignee: Nantero, Inc., Woburn, MA (US)

(21) Appl. No.: 12/537,510

(22) Filed: Aug. 7, 2009

(51) Int. Cl. H01L 21/302; H01L 21/20

(52) U.S. Cl. 438/478; 438/694; 977/742; 977/753; 977/773; 438/765; 257/E21.09; 257/E21.214

(57) ABSTRACT

A method of forming a textured surface on a substrate or material layer within a semiconductor fabrication process. In one aspect of the disclosure, a sacrificial nanofabric layer is deposited over a material layer and an etch process is used to transfer the surface texture of the nanofabric layer downward to the material layer. In another aspect of the disclosure, a thin material layer is deposited over a nanofabric layer such that the surface texture of the nanofabric layer is transferred upward to the material layer. Within both aspects, varying the porosity of nanofabric layer provides a measure of control over the degree of texturization of the material layer.

### CROSS-REFERENCE TO RELATED APPLICATIONS

This application is related to the following U.S. patents, which are assigned to the assignee of the present application, and are hereby incorporated by reference in their entirety:

Methods of Nanotube Films and Articles (U.S. Pat. No. 6,835,591), filed Apr. 23, 2002;

Methods of Using Pre-Formed Nanotubes to Make Carbon Nanotube Films, Layers, Fabrics, Ribbons, Elements, and Articles (U.S. Pat. No. 7,335,395), filed Jan. 13, 2003;

Devices Having Horizontally-Disposed Nanofabric Articles and Methods of Making the Same (U.S. Pat. No. 7,259,410), filed Feb. 11, 2004;

Devices Having Vertically-Disposed Nanofabric Articles and Methods of Making Same (U.S. Pat. No. 6,924,538), filed Feb. 11, 2004; and

Spin-Coatable Liquid for Formation of High Purity Nanotube Films (U.S. Pat. No. 7,375,369), filed Jun. 3, 2004.

This application is related to the following patent applications, which are assigned to the assignee of the application, and are hereby incorporated by reference in their entirety:

Methods of Making Carbon Nanotube Films, Layers, Fabrics, Ribbons, Elements, and Articles (U.S. patent application Ser. No. 10/341,005), filed Jan. 13, 2003; and

High Purity Nanotube Fabrics and Films (U.S. patent application Ser. No. 10/860,332), filed Jun. 3, 2004.

### TECHNICAL FIELD

The present invention relates to semiconductor fabrication, and more particularly to a method for forming a textured surface on a semiconductor substrate or material layer using a layer of nanofabric material.

### BACKGROUND

Any discussion of the related art throughout this specification should in no way be considered as an admission that such art is widely known or forms part of the common general knowledge in the field.

Within certain semiconductor devices, it is desirable to maximize the surface area of a material layer within a given cross-sectional area, or footprint. In one aspect, significantly increasing this ratio (surface area to footprint) significantly reduces the voltage required to generate an electric field about a given material. That is, by texturing the surface of a polysilicon electrode layer, for example, the voltage potential necessary to induce an electrical field required for a device operation is significantly reduced. In this way, the operating voltage of a device can be significantly reduced without increasing the overall size of a device. Such a technique is useful, for example, within high density memory arrays, wherein the cross-section area of individual memory cells must be minimized. Conversely, in electrical systems wherein large electric fields are necessary—such as, but not limited to, display systems, which must light a plurality of pixels, and so-called super capacitors, which must store a large amount of electrical energy in a relatively small physical area—such a technique can be used to realize an electrode layer which provides an enhanced electric field for a given operational voltage.

A plurality of conventional techniques for forming a textured surface on a substrate within a semiconductor fabrication process is well known to those skilled in the art. These include, but are not limited to, reactive ion etching (RIE) processes and thermal oxidation of a substrate formed by low pressure chemical vapor deposition (LPCVD). Specifically, U.S. Pat. No. 6,165,844 to Chang teaches a method for forming a textured surface on a polysilicone substrate via thermal oxidation. Further, U.S. Pat. No. 5,521,108 to Rostoker et al. teaches a process for forming a textured electrode element (referenced as a “conductive member” within said disclosure) wherein a mixture of germanium and silicon is oxidized.

While these prior art techniques are sufficient when used within certain manufacturing processes, they can be sub-optimal in other manufacturing processes. For example, these prior art techniques are often unsuitable for realizing small scale devices as they typically result in large asperities on the material surface. Moreover, these prior art processes often require multiple etching and/or oxidation steps, resulting in long process cycle times.

### SUMMARY OF THE DISCLOSURE

It is the object of the present disclosure to provide a method for forming a textured surface using a layer of nanofabric with a given porosity and surface texture.

In particular, the present disclosure provides a method for fabricating a textured surface on a layer within a semiconductor fabrication process, the method can include the steps of first forming a material layer, the material layer including a surface to be textured, then depositing a sacrificial nanofabric layer on the material layer, the nanofabric layer having a porosity, a thickness, a volume density, and a surface texture, then performing at least one of an etching processes and an oxidation on the sacrificial nanofabric layer, to create surface texture on said material layer.

The present disclosure also provides a method for fabricating a textured surface on a layer within a semiconductor fabrication process, the method can include the steps of first forming a nanofabric layer on a substrate, the nanofabric layer having a porosity, a thickness, a volume density, and a surface texture, then depositing a thin material layer on the nanofabric layer, the thin material layer conforming to the surface texture of the nanofabric layer.

In an embodiment of the present disclosure, a layer of material is deposited on a substrate in a first operation. In a second operation, a sacrificial layer of nanofabric—such as, but not limited to, a matted layer of carbon nanotubes—is deposited over said layer of material. The nanofabric layer has a porosity which is related to at least one of the volume density of elements within said nanofabric and the thickness of said nanofabric layer, the porosity providing control over the degree to which the surface of the material layer will be texturized. In a third operation, an etch process is used to remove the sacrificial nanofabric layer, creating surface texture from the nanofabric layer to the material layer below.

In an alternate embodiment, the third operation is completed with multiple etch and/or oxidation processes: a first etch process to transfer the texture of the nanofabric layer to the material layer below and a second etch process to remove the sacrificial layer of nanofabric.

In another alternate embodiment, a layer of nanofabric is deposited on a substrate in a first operation. In a second operation, a thin layer of material is deposited on the layer of nanofabric, said deposition operation providing an upward transfer of surface texture to the material layer. As in the preferred embodiment, said nanofabric layer has a porosity proportional to at least one of the volume density of elements within said nanofabric layer and the thickness of said nanofabric layer, said porosity providing control over the degree to which the surface of the material layer will be texturized.

Accordingly it is the object of the present disclosure to provide a method for forming a textured surface on a substrate or layer within a semiconductor fabrication process.

It is also an object of the present disclosure that said method include using a layer of nanofabric of a selected porosity to provide the surface texture.

It is further an object of the present disclosure to provide a measure of control over the degree to which a substrate or layer is texturized.

In some embodiments, the nanofabric layer can be a matted layer of carbon nanotubes, a monolayer of carbon nanotubes, a plurality of carbon nanoparticles or a mixture of carbon nanotubes and filler particles.

In some embodiments, the thickness of the nanofabric layer ranges from about 10 nm to about 500 nm.

In some embodiments, the method further includes removing the remainder of the sacrificial nanofabric layer after the etching or oxidation process.

In some embodiments, the material layer can be a semiconductor, a metal, or an insulator.

Other features and advantages of the present invention will become apparent from the following description of the invention which is provided below in relation to the accompanying drawings.

### BRIEF DESCRIPTION OF THE DRAWINGS

FIGS. 1A-1D illustrate the steps of an embodiment of the present disclosure wherein the surface texture of a nanofabric layer is transferred downward to a material layer;

FIG. 2 is a flow chart describing the process depicted in FIGS. 1A-1D;

FIGS. 3A-3C illustrate the steps in an alternate embodiment of the present disclosure wherein the surface texture of a nanofabric layer is transferred upward to a material layer;

FIG. 4 is a flow chart describing the process depicted in FIGS. 3A-3C.

### DETAILED DESCRIPTION

The present disclosure relates to semiconductor fabrication, and more particularly to a method for forming a textured surface on a semiconductor substrate or material layer using a layer of nanofabric material.

Texture, as used throughout this disclosure, refers to the surface topology of the material layer. For example, a textured surface of a material layer can have ridges, valleys, and bumps that extend into and out of the horizontal surface plane of the material layer.

By texturizing the surface of a polysilicon electrode layer, for example, the voltage potential necessary to induce an electrical field required for a device operation is significantly reduced. In this way, the operating voltage of a device can be significantly reduced without increasing the overall size of a device. Therefore, by creating a texture material layer or by introduced a higher level of texture into a material layer, the electrical performance of the material layer can be improved. Such a technique is useful, for example, within high density memory arrays, wherein the cross-section area of individual memory cells must be minimized. Further, textured material layers can produce larger electrical fields than non-textured material layers. Thus, in electrical systems wherein large electric fields are necessary—such as, but not limited to, display systems, which must light a plurality of pixels, and super capacitors, which must store a large amount of electrical energy in a relatively small physical area—a textured electrode layer can provide an enhanced electric field for a given operational voltage.

In one embodiment, the present disclosure uses a sacrificial nanotube fabric layer as a masking agent in order to texturize a material surface. With the porous nanotube fabric deposited over a material layer, some areas of the material's surface will be exposed through the voids and gaps within the nanotube fabric layer while other areas will be covered by the individual nanotube elements comprising the nanotube fabric layer.

An etch process performed after the deposition of the nanotube fabric layer, will tend to remove those areas of the material layer exposed through the pores in the nanotube fabric layer while those areas of the material layer protected by the individual nanotube elements will remain substantially unchanged.

Alternatively, an oxidation process performed after the deposition of the nanotube fabric layer will tend to react with the individual nanotube elements (for example, in the case where the individual nanotube elements are carbon nanotubes, the oxidation process will react with the carbon nanotube elements, essentially dissolving them away as carbon dioxide) and leave those areas of the material layer beneath the individual nanotube element substantially untouched. Those areas of the material layer exposed through the pores within the nanotube fabric layer will be free to oxidize (for example, in the case of a silicon material layer, forming areas of silicon dioxide).

In another embodiment, a thin material layer is deposited conformably over a porous nanotube fabric layer such that the texture of the nanotube fabric layer is transferred to the overlying material layer.

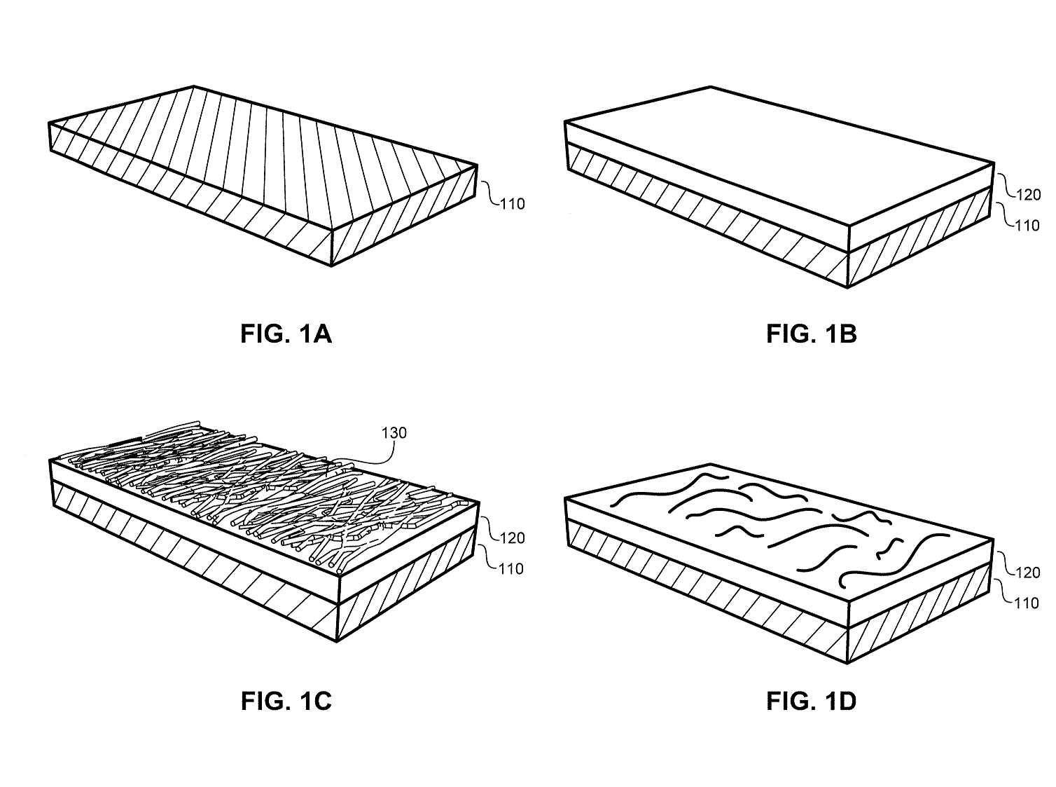

FIGS. 1A-1D illustrate an embodiment of the present disclosure. A layer of material 120 is deposited on a substrate 110 in a first operation as depicted in FIG. 1B. A plurality of materials can be used to form material layer 120, such as, but not limited to, semiconductors, polysilicon, metals, and insulating materials, dependant on the needs of the fabrication process. The methods and materials used to deposit such a layer on a substrate are well known to those skilled in the art. Exemplary thicknesses of the material layer range from about 10 nm to about 500 nm. In other embodiments, the substrate layer can be the material layer itself.

In a second operation (depicted in FIG. 1C), a sacrificial layer of nanofabric 130 is deposited on material layer 120. In an embodiment, this nanofabric layer 130 is a matted layer of carbon nanotubes, as depicted in FIG. 1C. However, the methods of the present disclosure are not limited in this regard. Indeed, this nanofabric layer 130 can take a plurality of forms, including, but not limited to, a monolayer of non-overlapping carbon nanotubes, a layer of carbon nanoparticles, and a mixture of carbon nanotubes and some inert filler material (such as, but not limited to, amorphous carbon and carbon black) wherein said mixture provides a measure of control over the volume density of carbon nanotubes in the layer. U.S. Pat. No. 7,335,395 to Ward et al., included herein by reference, teaches the fabrication and use of such nanofabric layers and films. Exemplary thicknesses of the nanofabric layer range from about 10 nm to about 500 nm. For example, for a monolayer of nanofabric, the thickness can range from about 10 nm to about 50 nm, while for a multilayer nanofabric the thickness can range from about 300 nm to about 400 nm.

Within an embodiment of the present disclosure, the nanofabric layer 130 is used as an etching masking layer and a carbon nanotube etch process is used in a third operation to both provide a downward transfer of surface texture to the material layer 120 and to remove the sacrificial nanofabric layer 130. In an alternate embodiment, the nanofabric layer is used as part of a differential oxidation process wherein the nanofabric layer is removed via a preferential etch process which leaves the underlying surface oxide intact. FIG. 1D depicts the final stage of this process wherein the nanofabric layer 130 has been removed and the material layer 120 is textured.

The porosity of nanofabric layer 130 is determined by the volume density of elements within the nanofabric (carbon nanotubes in the preferred embodiment) and the thickness of the layer 130 itself. By controlling one or both of these parameters (the volume density or thickness of the nanofabric), the degree of texturization of the material layer 120 can be controlled. For example, if the volume density of the fabric layer is low, i.e., there are few carbon nanotubes, there will be more gaps in the coating of the nanofabric and thus more places where the material layer is unprotected from the etchant. Therefore, a low volume density nanofabric layer will result in a highly textured material layer. However, if the volume density or thickness of the nanofabric layer is high, there will be fewer gaps in the coating of nanofabric over the material layer. Therefore, there will be less unprotected areas of the material layer. This will produce a material layer having a small amount of texture. That is, the porosity of the nanotube fabric layer 130 provides an improved measure of control (as compared with previously known techniques for texturizing a material surface) over the size of the textured features produced over surface 120. In this way the methods of the present disclosure can be optimized to meet the needs of a variety of applications, including, but not limited to, high density memory arrays, super capacitors, and display devices.

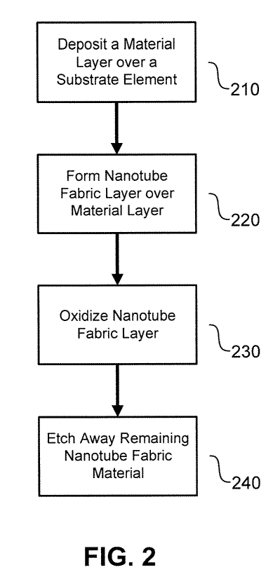

FIG. 2 is a block diagram describing an embodiment of the present disclosure as depicted in FIGS. 1A-1D. In a first process step 210, a material layer (analogous to material layer 120 in FIG. 1B) is deposited over a substrate element (analogous to substrate element 110 in FIG. 1B). In a second process step 220, a sacrificial porous nanotube fabric layer (analogous to nanotube fabric layer 130 in FIG. 1C) is deposited over the material layer. In a third process step 230, the sacrificial porous nanotube fabric layer is oxidized, allowing those regions of the material layer exposed through the sacrificial porous nanotube fabric layer to be partially etched or otherwise modified. Depending on the type of oxidization process used (such processes well known to those skilled in the art), some portion of the sacrificial porous nanotube fabric layer may be etched away as well. For certain oxidization processes, substantially all of the sacrificial porous nanotube fabric layer will be removed within process step 230. For other oxidation processes, the sacrificial porous nanotube fabric layer will remain substantially unmodified within process step 230. In a final process step 240, an etch process—such as, but not limited to, an oxygen plasma etch process—is used to remove any portion of the sacrificial porous nanotube fabric layer remaining over the now texturized material layer.

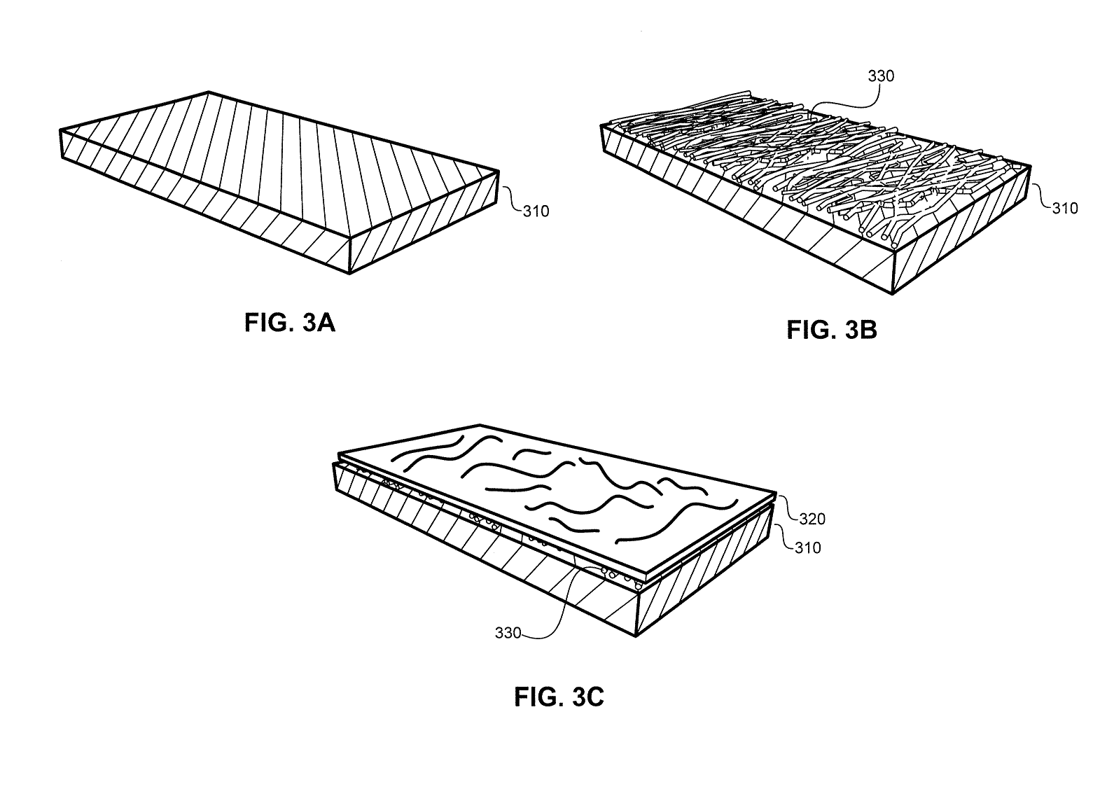

FIGS. 3A-3C illustrate an alternate embodiment of the present disclosure. A layer of nanofabric 330 is deposited onto a substrate 310 (as depicted in FIG. 3B). As in the preferred embodiment of the present disclosure, this nanofabric layer can take a plurality of forms, including, but not limited to, a matted layer of carbon nanotubes, a monolayer of non-overlapping nanotubes, a layer of carbon nanoparticles, and a mixture of carbon nanotubes and some inert filler material (such as, but not limited to, amorphous carbon and carbon black) wherein said mixture provides a measure of control over the volume density of carbon nanotubes in the layer.

In a second operation, a thin material layer 320 is deposited onto the nanofabric layer 330. The thickness of the material layer 320 can be sufficiently limited such that the surface texture of the nanofabric layer 330 is transferred upward to the material layer 320. FIG. 3C depicts the final stage of this process, wherein the material layer 320 has taken on the surface texture of the nanofabric layer 330. As in the preferred embodiment, the porosity of the nanofabric layer 330 provides a measure of control over the degree of texturization of the material layer 320, allowing the process to be optimized for a plurality of applications.

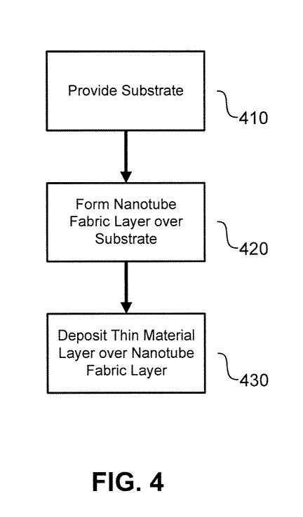

FIG. 4 is a block diagram describing the alternate embodiment of the present invention as depicted in FIGS. 3A-3D. In a first process step 410, a substrate element (analogous to substrate element 310 in FIG. 1A) is provided. In a second process step 420, a porous nanotube fabric layer (analogous to nanotube fabric layer 330 in FIG. 3B) is deposited over the substrate element. In a third process step 430, a thin material layer (analogous to material layer 320 in FIG. 3C) is deposited over the porous nanotube fabric layer. The material layer is kept relatively thin such that the material layer will tend to follow the contours and texture of the underlying nanotube fabric layer as it is deposited. While the present invention is not limited to any specific deposition method, material layers—such as, but not limited to, metals and polysilicon—deposited via chemical vapor deposition (CVD) are well suited for this embodiment of the present invention as layer deposited through a CVD process tend to readily conform to an underlying surface. In this way, the deposited material layer will be texturized as it is deposited.

Although the present invention has been described in relation to particular embodiments thereof, many other variations and modifications and other uses will become apparent to those skilled in the art. It is preferred, therefore, that the present invention not be limited by the specific disclosure herein.

What is claimed is:

1. A method for fabricating a textured surface on a material layer within a semiconductor fabrication process, said method comprising:
forming a material layer, said material layer including a surface to be textured;
depositing a sacrificial nanofabric layer on said surface to be textured of said material layer, said nanofabric layer having a porosity, a thickness, and a volume density; and
performing at least one of an etching process and an oxidation process on said sacrificial nanofabric layer to create surface texture on said material layer.

2. The method of claim 1 wherein said nanofabric layer comprises a matted layer of carbon nanotubes.

3. The method of claim 1, wherein said nanofabric layer comprises a monolayer of non-overlapping carbon nanotubes.

4. The method of claim 1, wherein said nanofabric layer comprises a plurality of carbon nanoparticles.

5. The method of claim 1, wherein said nanofabric layer comprises a mixture of carbon nanotubes and inert filler particles.

6. The method of claim 1, wherein said porosity of said nanofabric layer is selected to realize a desired degree of surface texturization on said material layer.

7. The method of claim 6, wherein said volume density of said nanofabric layer is selected to realize a desired porosity within said nanofabric layer.

8. The method of claim 6, wherein said thickness of said nanofabric layer is selected to realize a desired porosity within said nanofabric layer.

9. The method of claim 6, wherein said thickness of said nanofabric layer ranges from about 10 nm to about 500 nm.

10. The method of claim 6, wherein said material layer is selected from the group consisting of a semiconductor, a metal, and an insulator.

11. The method of claim 6 comprising removing the remainder of said sacrificial nanofabric layer after said performing step.

12. A method for fabricating a textured surface on a material layer within a semiconductor fabrication process, said method comprising:
forming a nanofabric layer on a surface, said nanofabric layer having a porosity, a thickness, a volume density, and a surface texture; and
depositing a thin material layer on said nanofabric layer, said thin material layer conforming to the surface texture of said nanofabric layer.

13. The method of claim 12, wherein said nanofabric layer comprises a matted layer of carbon nanotubes.

14. The method of claim 12, wherein said nanofabric layer comprises a monolayer of non-overlapping carbon nanotubes.

15. The method of claim 12, wherein said nanofabric layer comprises a plurality of carbon nanoparticles.

16. The method of claim 12, wherein said nanofabric layer comprises a mixture of carbon nanotubes and inert filler particles.

17. The method of claim 12, wherein the porosity of said nanofabric layer is selected to realize a desired degree of texturization in said material layer.

18. The method of claim 17, wherein said volume density of the nanofabric layer is selected to realize a desired porosity within said nanofabric layer.

19. The method of claim 17 wherein said thickness of the nanofabric layer is selected to realize a desired porosity within said nanofabric layer.

20. The method of claim 12, wherein said material layer is selected from the group consisting of a semiconductor, a metal, and an insulator.
